(19) United States
(12) Patent Application Publication
(10) Pub. No.: US 2022/0246892 A1
(43) Pub. Date: Aug. 4, 2022

(54) DISPLAY PANEL AND DISPLAY APPARATUS

(71) Applicant: KunShan Go-Visionox Opto-Electronics Co., Ltd, Kunshan (CN)

(72) Inventors: Mingxing LIU, Kunshan (CN); Chao Chi PENG, Kunshan (CN); Panpan WANG, Kunshan (CN); Zhiyuan ZHANG, Kunshan (CN); Xuyang FANG, Kunshan (CN)

(73) Assignee: KunShan Go-Visionox Opto-Electronics Co., Ltd, Kunshan (CN)

(21) Appl. No.: 17/725,913

(22) Filed: Apr. 21, 2022

Related U.S. Application Data
(63) Continuation of application No. PCT/CN2021/083223, filed on Mar. 26, 2021.

(30) Foreign Application Priority Data
May 18, 2020 (CN) 202010419601.1

(51) Int. Cl. H01L 51/52

(52) U.S. Cl. CPC H01L 51/5281; H01L 27/3244; H01L 51/5225

(57) ABSTRACT

A display panel and a display apparatus. The display panel includes a light-transmitting area and a display area at least partially surrounding the light-transmitting area, and a light-shielding area is disposed between the display area and the light-transmitting area. An array substrate and a light-emitting layer disposed on the array substrate are disposed in the display area, and at least one light-shielding layer is disposed in the light-shielding area to prevent light emitted by the light-emitting layer in the display area from entering the light-transmitting area. The embodiments can effectively block the light in the display area from transmitting through the light-transmitting area, and reduce the light leakage rate of the display panel, thereby optimizing the display effect of the display panel and the display apparatus, and meanwhile being conductive to manufacturing the display panel with a narrow frame.

### CROSS-REFERENCE TO RELATED APPLICATIONS

The present application is a continuation of International Application No. PCT/CN2021/083223, filed on Mar. 26, 2021, which claims priority to Chinese Patent Application No. 202010419601.1 filed with the China National Intellectual Property Administration on May 18, 2020 and entitled “display panel and display apparatus”. The disclosures of the aforementioned applications are hereby incorporated by reference in their entireties.

### TECHNICAL FIELD

The present application relates to display technology field and, in particular, to a display panel and a display apparatus.

### BACKGROUND

In current display technology field, as people have higher and higher requirements for screen-to-body ratio and display effect, display devices with a full-screen are favored by general users. The full-screen may not only improve aesthetics on appearance of the display devices, but also reduce the size of mobile phones, and bring a better visual experience for users.

Based on that the display devices need to be equipped with additional functional devices such as a fingerprint recognition, an earpiece, a distance sensing sensor, a light sensor, and a camera apparatus, etc., therefore, there is a need to reserve a certain area on a display screen for setting the additional functional devices. At present, a hole structure may be disposed on some of the display screens, and the above-mentioned additional functional devices are disposed in a position of the hole structure in a display panel. However, there will be a phenomenon of light leakage from the hole structure. In order to prevent the phenomenon of light leakage from the hole structure, a common method is coating a light-shielding ink in a sealing cover-plate near the hole structure of the display screen. The ink is used to shield light emitted by a light-emitting layer, and the light is blocked from diverging from the hole structure to a display surface of the display screen, so as to achieve the objective of reducing light leakage of the display screen.

However, the current ink coating technology has a relatively low precision, resulting in the relatively poor light-shielding effect of the coated ink. This not only reduces the display effect of the display screen, but also increases the width of a frame of the display screen, which is not conducive to manufacturing display screens with a narrow frame.

### SUMMARY

In order to solve at least one problem mentioned in the background art, the present application provides a display panel and a display apparatus, which can effectively block light in a display area from transmitting through a light-transmitting area, and reduce the light leakage rate of the display panel, thereby optimizing the display effect of the display panel and the display apparatus, and meanwhile being conductive to manufacturing the display panel with a narrow frame.

In order to achieve the above objectives, in a first aspect, the present application provides a display panel, including a light-transmitting area and a display area at least partially surrounding the light-transmitting area, and a light-shielding area is disposed between the display area and the light-transmitting area. An array substrate and a light-emitting layer disposed on the array substrate are disposed in the display area, and at least one light-shielding layer is disposed in the light-shielding area to prevent light emitted by the light-emitting layer in the display area from entering the light-transmitting area.

For the display panel provided in the present application, by disposing the light-transmitting area, such as disposing a blind hole or a through hole, on the display panel for installing additional functional devices such as a camera module, an earpiece, and a light sensor, etc., the screen-to-body ratio of the display panel is increased, which is conducive to realizing full-screen display. By disposing the light-shielding area between the light-transmitting area and the display area disposed to surround the light-transmitting area, and using the light-shielding layer in the light-shielding area to shield the light emitted from the light-emitting area from diverging to the light-transmitting area, the light leakage rate of the display panel is thus effectively reduced, and the display quality of the display panel is improved. Moreover, compared that the light-shielding layer is located at a side of the light-emitting layer close to a light-output surface of the display panel, with that the light-shielding ink is disposed on the sealing cover-plate in the prior art, the distance between the light-shielding layer and the light-emitting layer in the present application is reduced, and the light-shielding size is larger. This not only increases light-shielding effect, but also reduces the setting width of the light-shielding layer, which is more conducive to manufacturing the display panel with a narrow frame and a full-screen.

In a second aspect, the present application further provides a display apparatus, the display apparatus includes the above-mentioned display panel.

### BRIEF DESCRIPTION OF DRAWINGS

FIG. 1 is a structural schematic diagram of a display panel provided in a first embodiment of the present application.

FIG. 2 is a cross-section diagram along line A-A in FIG. 1 provided in the first embodiment of the present application.

FIG. 3 is a structural schematic diagram of a first light-shielding layer of the display panel provided in the first embodiment of the present application.

FIG. 4 is a schematic diagram of the influence of the distance between a light-shielding layer and a light-emitting layer of the display panel provided in the first embodiment of the present application on light-shielding effect.

FIG. 5 is a structural schematic diagram of a light-extracting layer, a polarizing layer, and a touch layer of the display panel provided in the first embodiment of the present application.

FIG. 6 is a structural schematic diagram of a second light-shielding layer of a display panel provided in a second embodiment of the present application.

FIG. 7 is a structural schematic diagram of a first light-shielding layer and a second light-shielding layer of a display panel provided in a third embodiment of the present application.

FIG. 8 is a structural schematic diagram of a light-shielding layer of a display panel provided in a fourth embodiment of the present application.

### DETAILED DESCRIPTION OF THE EMBODIMENTS

In current display panels, a phenomenon of light leakage appears in a hole structure for installing additional functional devices such as an earpiece, a light sensor, and a camera apparatus, etc. The hole structure may include a blind hole structure or a through hole structure. For example, the blind hole structure may include a supporting layer and a sealing cover-plate that are disposed oppositely, where a camera module is disposed under the supporting layer, and external light enters the camera module through the blind hole structure to complete camera function. However, light emitted by a light-emitting device in a display area will diverge around, and part of the light may diverge to a display surface of the display panel through the hole structure, so as to cause the phenomenon of light leakage in the hole structure of the display panel. The above phenomenon of light leakage of the display panel not only influences the display effect of the display panel, but also can influence the imaging effect of the camera module of a display apparatus.

At present, a common solution to this problem is coating a light-shielding ink on the sealing cover-plate at a position close to the display area in the hole structure, and the light-shielding ink is used to block the light emitted by the light-emitting device (such as OLED device) in the display area from diverging from the hole structure to the display surface of a display screen. However, the current ink coating technology has a relatively low precision, and when the ink is coated on the sealing cover-plate, the distance of the ink to the light-emitting layer is relatively far, which reduces the size of an effective light-shielding area, results in the relatively poor light-shielding effect of the coated ink, and thus reduces the display effect of the display screen. Further, a boundary of an ink-coating area is not regular, which will increase the width of a frame of the hole structure, thereby reducing the screen-to-body ratio of the display panel.

In view of this, in an embodiment of the present application, by disposing a light-transmitting area on a display panel, and disposing functional devices such as a camera module, an earpiece, or a light sensor, etc. at a position corresponding to the light-transmitting area, the screen-to-body ratio of the display panel is increased, which is conducive to realizing full-screen display. By disposing a light-shielding area between the light-transmitting area and a display area disposed to at least partially surround the light-transmitting area, and disposing a light-shielding layer in the light-shielding area to shield light emitted from a light-emitting area from diverging, such as diverging to a display surface of the display panel, through the light-transmitting area, the light leakage rate of the display panel is thus effectively reduced, and the display effect of the display panel is improved. Moreover, compared that the light-shielding layer is located at a side of the light-emitting layer close to a light-output surface of the display panel, with that the light-shielding ink is disposed on the sealing cover-plate in the prior art, the distance between the light-shielding layer and the light-emitting layer in the present application is reduced, that is, the distance between the light-shielding layer and a light source is reduced, and the light-shielding size is larger. This not only increases light-shielding effect, but also reduces the setting width of the light-shielding layer, which is more conducive to reducing the frame between the light-transmitting area and the display area.

In order to make the objectives, technical solutions and advantages of the present application clearer, the technical solutions in embodiments of the present application will be described in more detail below in combination with the drawings in preferred embodiments of the present application.

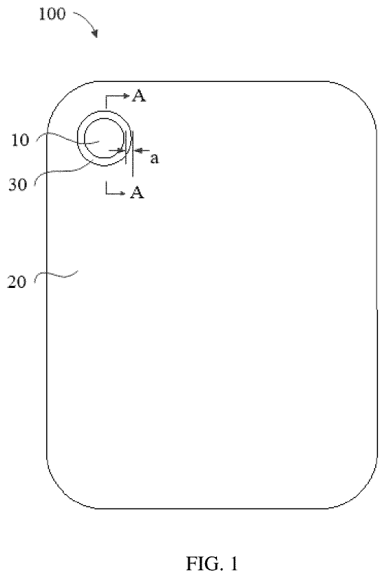

Referring to FIGS. 1 to 5, the present application provides a display panel 100, which includes a light-transmitting area 10 and a display area 20 at least partially surrounding the light-transmitting area 10, and a light-shielding area 30 is disposed between the display area 20 and the light-transmitting area 10.

An array substrate 24 and a light-emitting layer disposed on the array substrate 24 are disposed in the display area 20. Optionally, an encapsulation layer 50 is disposed on the display area 20, the light-shielding area 30, and the light-transmitting area 10.

At least one light-shielding layer 31 is disposed in the light-shielding area 30, and the light-shielding layer 31 is configured to prevent light emitted by the light-emitting layer in the display area 20 from entering the light-transmitting area 10.

It should be noted that, referring to FIG. 1, the light-transmitting area 10 provided in the present application may be located at any position on the display panel 100, such as an upper left corner position illustrated in FIG. 1. Those skilled in the art may understand that, the light-transmitting area 10 may also be disposed at an upper middle position, an upper right position, and a lower middle position, etc. of the display panel 100 in actual use, which is not limited by the present embodiment, and also not limited to the above-mentioned examples and the illustration of FIG. 1.

Optionally, the structure of the light-transmitting area 10 may include a blind hole structure or a through hole structure.

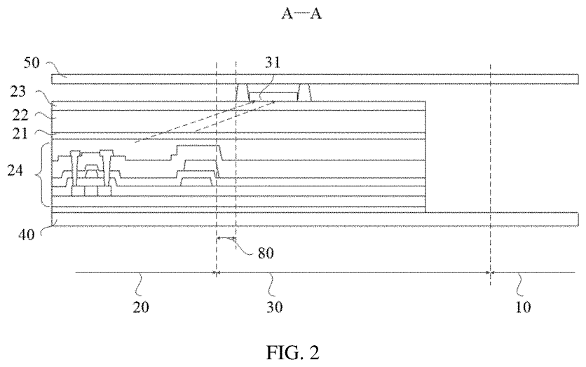

Referring to FIG. 2, a first substrate 40, the array substrate 24, the light-emitting layer, and the encapsulation layer 50 are stacked in sequence in the display area 20 of the display panel 100 of the present embodiment. Where the first substrate 40 may include, but is not limited to, a glass substrate and a PI (Polyimide) substrate, a light-transmitting PET (Polyethylene terephthalate) substrate, and a flexible glass substrate. The array substrate 24 may include, but is not limited to, an array circuit P-S, an M1/M2/M3 metal layer, a buffer layer, and a GI-Si/CI-Si common layer. The encapsulation layer 50 may include, but is not limited to, a glass encapsulation layer. Where the encapsulation layer 50 and the first substrate 40 are both made of a light-transmitting material. Only the encapsulation layer 50 and the first substrate 40 are disposed in the light-transmitting area 10, and a bottom of the first substrate 40 may be provided with structural components such as a sensor with various functions and a camera module.

The present embodiment takes that the camera module is correspondingly disposed in the light-transmitting area 10 as an example. Based on that the encapsulation layer 50 and the first substrate 40 are both light-transmitting structures, external light may enter the camera module at the bottom of the first substrate 40 through both the encapsulation layer 50 and the first substrate 40, so as to ensure the normal light acquisition of the camera module, and realize the camera function of the display apparatus. A specific structure of the camera module is not limited by the present embodiment, and it may be a common camera module structure used in the prior art.

There is a spacer area between an edge of the light-transmitting area 10 and a frame of the display panel 100 to prevent the light-transmitting area 10 from being too close to the frame of the display panel 100, thereby reducing the mechanical strength of the display panel 100 in the spacer area. In actual use, the width of the spacer area may be set according to actual needs, which is not limited by the present embodiment.

Further, in order to ensure that no light emitted by the light-emitting layer exists in the light-transmitting area 10, the light-shielding area 30 is disposed between the display area 20 and the light-transmitting area 10 in the present embodiment. In the light-shielding area 30, at least one light-shielding layer 31 is disposed at a side of the light-emitting layer close to a light-output surface of the display panel 100. Where the side of the light-emitting layer close to the light-output surface of the display panel 100 refers to a side of the light-emitting layer close to the encapsulation layer 50, that is, the light-shielding layer 31 is located between the light-emitting layer and the encapsulation layer 50. The structure setting that the light-shielding layer 31 is located between the light-emitting layer and the encapsulation layer 50 has following advantages: firstly, compared to the existing light-shielding ink coated on the encapsulation layer 50, the distance between the light-shielding layer 31 and the light-emitting layer is closer.

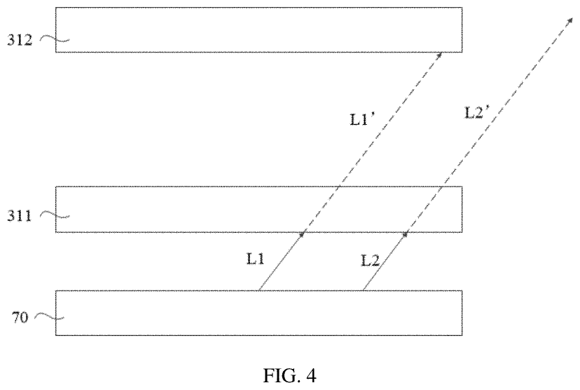

Those skilled in the art may understand that, referring to FIG. 4, the closer the light-shielding layer 31 is to the light-emitting layer, the larger the effective light-shielding area of the light-shielding layer 31 is for the light-emitting layer. A light-shielding layer closer to the light-emitting layer 70 in FIG. 4 may be a first light-shielding layer 311 of the present embodiment. The first light-shielding layer 311 may simultaneously shield two beams of light L1 and L2. Supposing that the two beams of light reach a light-shielding layer farther from the light-emitting layer 70 along light paths, the farther light-shielding layer may be a second light-shielding layer 312 of the present embodiment. The second light-shielding layer 312 can only shield light L1′, and cannot shield light L2′. Therefore, the distance between the light-shielding layer 31 and the light-emitting layer is set closer in the present embodiment, which may increase the size of the effective light-shielding area of the light-shielding layer 31. This may not only increase the light-shielding effect of the light-shielding layer 31, but also may effectively reduce the required size of the light-shielding layer 31 when the distance between the light-shielding layer 31 and the light-emitting layer is closer under the premise of the same light-shielding effect. Therefore, in order to achieve the same light-shielding effect on the display panel 100, the size of the light-shielding area 30 is smaller, which is conducive to increasing the screen-to-body ratio of the display panel 100 and reducing the width of the frame between the display area 20 and the light-transmitting area 10.

Secondly, the light-shielding layer 31 is located between the light-emitting layer and the encapsulation layer 50, and the encapsulation layer 50 may be used to protect the light-shielding layer 31, thereby improving the stability of the setting of the light-shielding layer 31.

Specifically, referring to FIG. 2, the light-emitting layer includes a first electrode layer 21, a pixel layer 22 and a second electrode layer 23 which are stacked on the array substrate 24 in sequence, and the light-shielding layer 31 is located between the second electrode layer 23 and the encapsulation layer 50.

It should be noted that the first electrode layer 21 provided in the present embodiment may be one of an anode layer and a cathode layer, and the second electrode layer 23 may be the other one of the two, which is not limited by the present embodiment. The present embodiment takes that the second electrode layer 23 close to the light-shielding layer 31 is the cathode layer as an example for description. The cathode layer may be selected to a single layer of metal, such as Al, Mg, Ca, and Ag, etc.; may also be selected to an alloy material, such as Al/Mg alloy or Ag/Mg alloy; and may further be selected to a planer cathode. The cathode layer is a dual electrode formed by Al and a compound like LiF, CsF, RbF, etc. At least one insulating layer 60 is disposed between the encapsulation layer and the second electrode layer 23. By disposing the insulating layer 60, the insulating layer 60 may be used to effectively block the electrical contact between the second electrode layer 23 and metal material layers in the display panel 100, thereby preventing the second electrode layer 23 from being influenced by other metal material layers, and improving the stability of power supply of the second electrode layer 23 to the pixel layer 22, therefore, the work performance of the display apparatus is greatly improved.

It needs to be pointed out that, based on that the metal Ag has a certain shielding effect on light, so that if the material of the cathode is selected to Ag/Mg alloy, the content of Ag is relatively low, or is lower than the content of Mg, so as to ensure that the cathode has a sufficient light-transmitting effect.

As a realizable embodiment, a surface of the light-shielding layer 31 close to the second electrode layer 23 is a flat surface. By setting the surface of the light-shielding layer 31 close to the second electrode layer 23 as a plane, it is convenient to installing the light-shielding layer 31 to be attached to an adjacent structural layer, thereby reducing the manufacture difficulty of the display panel 100 and improving manufacture efficiency.

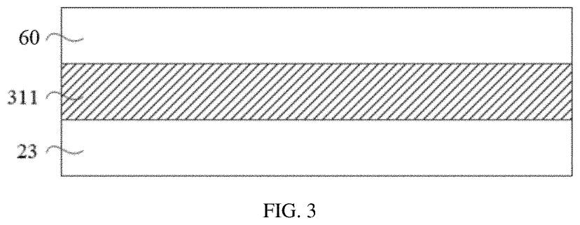

Specifically, referring to FIG. 3, the light-shielding layer 31 includes the first light-shielding layer 311 disposed between the second electrode layer 23 and the insulating layer 60, and the first light-shielding layer 311 is attached to the second electrode layer 23.

Based on the above-mentioned description, the first light-shielding layer 311 is attached to the second electrode layer 23 in the present embodiment. This may ensure that the first light-shielding layer 311 is closer to the pixel layer 22, thereby increasing the size of the effective light-shielding area of the light-shielding layer 31, enhancing light-shielding effect, and reducing the width of the light-shielding layer 31, which is conducive to manufacturing the display panel 100 with a narrow frame.

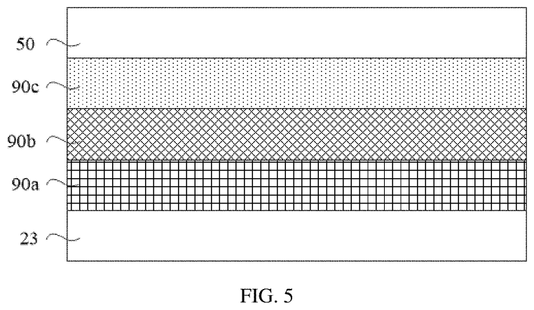

As a realizable embodiment, referring to FIG. 5, a light-extracting layer 90a, a polarizing layer 90b, and a touch layer 90c (Touch Panel), etc. may be included between the second electrode layer 23 and the encapsulation layer 50. Where the light-extracting layer 90a is located at a side of the second electrode layer 23 away from the array substrate 24, the touch layer 90c is located at a side of the encapsulation layer 50 close to the array substrate 24, and the polarizing layer 90b is located between the light-extracting layer 90a and the touch layer 90c.

The first light-shielding layer 311 may be disposed between any adjacent film layers of structural layers such as the light-extracting layer 90a, the polarizing layer 90b, and the touch layer 90c between the second electrode layer 23 and the encapsulation layer 50. In actual use, a user may set the first light-shielding layer 311 at a required position according to requirements, which is not limited by the present embodiment. Based on that the first light-shielding layer 311 is closer to the light-emitting layer 70, the light-shielding size and light-shielding effect are better. Therefore, in order to ensure the light-shielding effect of the first light-shielding layer 311, the first light-shielding layer 311 may be disposed as close to the light-emitting layer 70 as possible.

As a realizable embodiment, the first light-shielding layer 311 is any one of, or a composite layer of more of a silver layer, a magnesium layer, a lithium layer, an aluminum layer, a magnesium-silver alloy layer, and a lithium-aluminum alloy layer. In actual use, the first light-shielding layer 311 may have a material same as or different from the second electrode layer 23. When the first light-shielding layer 311 has a material same as the second electrode layer 23, types of materials in the display panel 100 may be effectively reduced. It needs to be pointed out herein that when the first light-shielding layer 311 is selected to the same Ag/Mg alloy as the second electrode layer 23, in order to ensure the light-shielding effect of the first light-shielding layer 311, the content of Ag in the Ag/Mg alloy is relatively high, or is higher than the content of Mg.

As a realizable embodiment, the light-shielding area 30 has a width of 0.3-0.5 mm Referring to FIG. 5, the width of the light-shielding area 30 may be represented by “a” in FIG. 1. When the width of the light-shielding area 30 is relatively small, the light-shielding effect on the light of the light-emitting layer cannot be ensured, thereby increasing the light leakage rate of the display panel 100 and influencing the display effect of the display panel 100. However, when the width of the light-shielding area 30 is relatively large, the screen-to-body ratio of the display panel 100 will be reduced, which is not conducive to manufacturing the display panel 100 with a full-screen. Therefore, in actual use, a user may select a specific width value of the light-shielding area 30 within the above-mentioned range, which is not limited by the present embodiment.

Where, referring to FIG. 2, an adjacent area 80 is disposed at a side of the light-shielding area 30 close to the display area 20, and at least part of the array substrate 24 and at least part of the light-emitting layer extend into the adjacent area 80.

It should be noted that the adjacent area 80 is located in the light-shielding area 30 and located at a junction between the light-shielding area 30 and the display area 20. The array substrate 24 and the light-emitting layer in the display area 20 extend into the adjacent area 80. During a light-emitting process of the display panel 100, by controlling the input of a light-emitting signal on the array substrate 24 in the adjacent area 80, the objective of controlling the light-emitting layer of the adjacent area 80 to emit light may be achieved. The light-emitting layer in the adjacent area 80 emits light so that a boundary between the display area 20 and the light-shielding area 30 also has sufficient light, and the light thus may fill the display area 20, which avoids obvious boundaries or black spots from appearing at the boundary between the display area 20 and the light-shielding area 30, and optimizes the display effect of the display panel 100. Moreover, this adjacent area 80 is close to the display area 20, which may effectively prevent light in the adjacent area 80 from entering the light-transmitting area, and reduce the light leakage rate of the display panel 100.

As a realizable embodiment, the array substrate 24 and the light-emitting layer may extend into the light-shielding area 30, or cover the entire light-shielding area 30, that is, end portions of the array substrate 24 and the light-emitting layer may extend to a junction between the light-shielding area 30 and the light-transmitting area 10. However, during the light-emitting process of the display panel 100, the light-emitting layer close to the light-transmitting area 10 is controlled not to emit light, so as to prevent the light from entering the light-transmitting area 10. A method for controlling the light-emitting layer close to the light-transmitting area 10 not to emit light may be disposing no light-emitting material in the light-emitting layer close to the light-transmitting area 10, or inputting no light-emitting signal to the array substrate 24 close to the light-transmitting area 10, which is not limited by the present embodiment. Further, the array substrate 24 and the light-emitting layer extend into the light-shielding area 30, which may also produce supporting effect on the light-shielding area 30 to prevent the setting of the light-transmitting area 10 from influencing the structural stability of the light-shielding area 30.

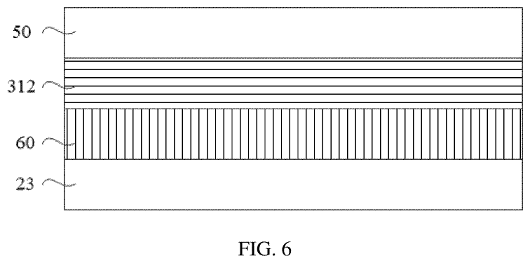

Referring to FIG. 6, on the basis of the above-mentioned first embodiment, a second embodiment of the present application provides a display panel. Comparing the second embodiment with the first embodiment, the difference between the two is: setting positions of the light-shielding layer 31 are different.

Specifically, the light-shielding layer 31 includes a second light-shielding layer 312 disposed between the insulating layer 60 and the encapsulation layer 50, and the second light-shielding layer 312 is spaced apart from the second electrode layer 23 by the insulating layer 60.

It should be noted that a single-layer light-shielding layer or a composite light-shielding layer may be selected for the second light-shielding layer 312. A material of the second light-shielding layer 312 may include one or more of silver, magnesium, lithium, aluminum, magnesium-silver alloy, and lithium-aluminum alloy. The material of the second light-shielding layer 312 may be the same as the material of the second electrode layer 23 or other metal materials. When the second light-shielding layer 312 is attached to the second electrode layer 23, the second light-shielding layer 312 will produce a certain influence on the power supply process of the second electrode layer 23. Therefore, the insulating layer 60 is disposed between the second light-shielding layer 312 and the second electrode layer 23, and the insulating layer 60 is used to block the electrical contact between the second light-shielding layer 312 and the second electrode layer 23, thereby reducing the influence of the second light-shielding layer 312 on the second electrode layer 23, and ensuring the stable power supply of the second electrode layer 23 to the light-emitting layer.

Other technical features are the same as those of the first embodiment, and can achieve the same technical effects, which will not be repeatedly described here.

For a display panel provided in a second embodiment of the present application, by disposing a light-transmitting area, such as disposing a blind hole or a through hole for installing additional functional devices such as a camera module, a earpiece, and a light sensor, etc., the screen-to-body ratio of the display panel is increased, which is conducive to realizing full-screen display. By disposing a light-shielding area between the light-transmitting area and a display area disposed to surround the light-transmitting area, and using a light-shielding layer in the light-shielding area to shield light emitted from a light-emitting area from diverging to the light-transmitting area, the light leakage rate of the display panel is thus effectively reduced, the display quality of the display panel is improved, and the influence of the light on the additional functional devices in the light-transmitting area is reduced. Moreover, compared that the light-shielding layer is located at a side of the light-emitting layer close to a light-output surface of the display panel, with that the light-shielding ink is disposed on the sealing cover-plate in the prior art, the distance between the light-shielding layer and the light-emitting layer in the present application is reduced, and the light-shielding size is larger. This not only increases the light-shielding effect, but also reduces the setting width of the light-shielding layer, which is more conducive to manufacturing the display panel with a narrow frame and a full-screen.

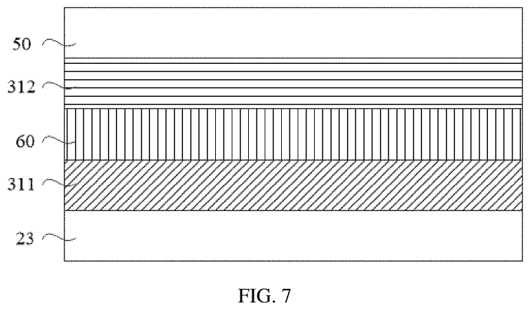

Referring to FIG. 7, on the basis of the above-mentioned first embodiment or second embodiment, a third embodiment of the present application provides a display panel. Comparing the third embodiment with the first embodiment or the second embodiment, the difference is: numbers and setting positions of the light-shielding layer 31 are different.

Specifically, at least one light-shielding layer 31 includes the first light-shielding layer 311 disposed between the second electrode layer 23 and the insulating layer 60 and the second light-shielding layer 312 disposed between the insulating layer 60 and the encapsulation layer 50.

It should be noted that the increase of the size of the effective light-shielding area for the light-emitting layer by the first light-shielding layer 311 enhances light-shielding effect, and part of reflected light on the second electrode layer 23 is shielded by the second light-shielding layer 312, thereby effectively reducing light that transmits through the light-transmitting area 10 to optimize the display effect of the display panel.

As a realizable embodiment, the same as the first embodiment is that a single-layer light-shielding layer or a composite light-shielding layer may be selected for the first light-shielding layer 311 and the second light-shielding layer 312. The material of the first light-shielding layer 311 and the second light-shielding layer 312 may include one or more of silver, magnesium, lithium, aluminum, magnesium-silver alloy, and lithium-aluminum alloy. Alternatively, the second light-shielding layer 312 may also be a black organic layer, and a black ink may be selected for the black organic layer.

Other technical features are the same as those of the first embodiment or the second embodiment, and can achieve the same technical effects, which will not be repeatedly described here.

For a display panel provided in a third embodiment of the present application, by disposing a light-transmitting area, such as disposing a blind hole or a through hole for installing additional functional devices such as a camera module, an earpiece, and a light sensor, etc., the screen-to-body ratio of the display panel is increased, which is conducive to realizing full-screen display. By disposing a light-shielding area between the light-transmitting area and a display area disposed to surround the light-transmitting area, and using a light-shielding layer in the light-shielding area to shield light emitted from a light-emitting area from diverging to the light-transmitting area, the light leakage rate of the display panel is thus effectively reduced, the display quality of the display panel is improved, and the influence of the light on the additional functional devices in the light-transmitting area is reduced. Moreover, compared that the light-shielding layer is located at a side of the light-emitting layer close to a light-output surface of the display panel, with that the light-shielding ink is disposed on the sealing cover-plate in the prior art, the distance between the light-shielding layer and the light-emitting layer in the present application is reduced, and the light-shielding size is larger. This not only increases the light-shielding effect, but also reduces the setting width of the light-shielding layer, which is more conducive to manufacturing the display panel with a narrow frame and a full-screen.

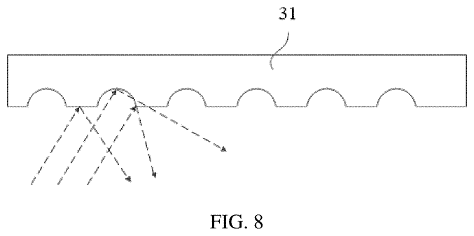

Referring to FIG. 8, on the basis of the above-mentioned first embodiment to third embodiment, a fourth embodiment of the present application provides a display panel. Comparing the fourth embodiment with the first embodiment to the third embodiment, the difference is: structures of a surface of a side of the light-shielding layer 31 close to the light-emitting layer are different.

Specifically, the surface of the light-shielding layer 31 close to the second electrode layer 23 is rough. It should be noted that by setting the surface of the side of the light-shielding layer 31 close to the second electrode layer 23 as an uneven rough structure, light of the light-emitting layer is diffusely reflected at the light-shielding layer 31, thereby reducing the light that transmits through the light-shielding layer 31, and reducing the reflected light that transmits through metal layers in the display panel. Therefore, the light-shielding effect is improved and the display effect of the display panel is optimized.

Other technical features are the same as those of the first embodiment to the third embodiment, and can achieve the same technical effects, which will not be repeatedly described here.

For a display panel provided in a fourth embodiment of the present application, by disposing a light-transmitting area, such as disposing a blind hole or a through hole for installing additional functional devices such as a camera module, an earpiece, and a light sensor, etc., the screen-to-body ratio of the display panel is increased, which is conducive to realizing full-screen display. By disposing a light-shielding area between the light-transmitting area and a display area disposed to surround the light-transmitting area, and using a light-shielding layer in the light-shielding area to shield light emitted from a light-emitting area from diverging to the light-transmitting area, the light leakage rate of the display panel is thus effectively reduced, the display quality of the display panel is improved, and the influence of the light on the additional functional devices in the light-transmitting area is reduced. Moreover, compared that the light-shielding layer is located at a side of the light-emitting layer close to a light-output surface of the display panel, with that the light-shielding ink is disposed on the sealing cover-plate in the prior art, the distance between the light-shielding layer and the light-emitting layer in the present application is reduced, and the light-shielding size is larger. This not only increases the light-shielding effect, but also reduces the setting width of the light-shielding layer, which is more conducive to manufacturing the display panel with a narrow frame and a full-screen.

On the basis of the above-mentioned first embodiment to fourth embodiment, a fifth embodiment of the present application provides a display apparatus. The display apparatus provided in the present embodiment may be any product or component with a display function, such as a television, a digital camera, a mobile phone, a tablet computer, a smart watch, an e-book, a navigator, and the like that include the above-mentioned display panel 100.

Other technical features are the same as those of the first embodiment to the fourth embodiment, and can achieve the same technical effects, which will not be repeatedly described here.

For a display panel provided in a fifth embodiment of the present application, by disposing a light-transmitting area on the display panel, such as disposing a blind hole or a through hole for installing additional functional devices such as a camera module, an earpiece, and a light sensor, etc., the screen-to-body ratio of the display panel is increased, which is conducive to realizing full-screen display. By disposing a light-shielding area between the light-transmitting area and a display area disposed to surround the light-transmitting area, and using a light-shielding layer in the light-shielding area to shield light emitted from a light-emitting area from diverging to the light-transmitting area, the light leakage rate of the display panel is thus effectively reduced, the display quality of the display panel is improved, and the influence of the light on the additional functional devices in the light-transmitting area is reduced. Moreover, compared that the light-shielding layer is located at a side of the light-emitting layer close to a light-output surface of the display panel, with that the light-shielding ink is disposed on the sealing cover-plate in the prior art, the distance between the light-shielding layer and the light-emitting layer in the present application is reduced, and the light-shielding size is larger. This not only increases the light-shielding effect, but also reduces the setting width of the light-shielding layer, which is more conducive to manufacturing the display panel with a narrow frame and a full-screen.

The foregoing respective embodiments are merely intended for describing the technical solutions of the present application other than limiting the present application. Although the present application has been described in detail with reference to the foregoing embodiments, those of ordinary skill in the art should understand that they may still make modifications to the technical solutions described in the foregoing embodiments, or make equivalent substitutions to some or all of the technical features therein. These modifications or substitutions do not make the essence of the corresponding technical solutions departs from the scope of the technical solutions of embodiments of the present application.

What is claimed is:

1. A display panel, comprising:
a light-transmitting area;
a display area at least partially surrounding the light-transmitting area, an array substrate and a light-emitting layer disposed on the array substrate being disposed in the display area; and
a light-shielding area located between the display area and the light-transmitting area, at least one light-shielding layer being disposed in the light-shielding area for preventing light emitted by the light-emitting layer in the display area from entering the light-transmitting area.

2. The display panel according to claim 1, wherein an encapsulation layer is disposed at a side of the light-emitting layer away from the array substrate, and the light-shielding layer is located between the light-emitting layer and the encapsulation layer.

3. The display panel according to claim 2, wherein the light-emitting layer comprises a first electrode layer, a pixel layer and a second electrode layer which are stacked on the array substrate in sequence; and
at least part of the second electrode layer extends into the light-shielding area.

4. The display panel according to claim 3, wherein in the light-shielding area, the light-shielding layer is located at a side of the second electrode layer away from the first electrode layer.

5. The display panel according to claim 3, wherein the encapsulation layer is disposed in the display area, the light-shielding area, and the light-transmitting area, and the light-shielding layer is located between the second electrode layer and the encapsulation layer.

6. The display panel according to claim 4, wherein at least one insulating layer is disposed between the second electrode layer and the encapsulation layer.

7. The display panel according to claim 5, wherein a surface of the light-shielding layer close to the second electrode layer is a flat surface;
or the surface of the light-shielding layer close to the second electrode layer is rough.

8. The display panel according to claim 6, wherein the light-shielding layer is disposed between the second electrode layer and the insulating layer;
or the light-shielding layer is disposed between the insulating layer and the encapsulation layer.

9. The display panel according to claim 6, wherein the light-shielding layer comprises a first light-shielding layer disposed between the second electrode layer and the insulating layer and a second light-shielding layer disposed between the insulating layer and the encapsulation layer; and
the first light-shielding layer is attached to the second electrode layer.

10. The display panel according to claim 1, wherein an adjacent area is disposed at a side of the light-shielding area close to the display area, and at least part of the array substrate and at least part of the light-emitting layer extend into the adjacent area.

11. The display panel according to claim 9, wherein a single-layer light-shielding layer or a composite light-shielding layer is selected for the first light-shielding layer and the second light-shielding layer;
wherein a material of the first light-shielding layer comprises one or more of silver, magnesium, lithium, aluminum, magnesium-silver alloy, and lithium-aluminum alloy; and
a material of the second light-shielding layer comprises one or more of silver, magnesium, lithium, aluminum, magnesium-silver alloy, and lithium-aluminum alloy, or the material of the second light-shielding layer comprises a black organic material.

12. The display panel according to claim 1, wherein a spacer area is provided between the light-transmitting area and a frame of the display panel.

13. The display panel according to claim 5, wherein a light-extracting layer, a polarizing layer, and a touch layer are stacked in sequence between the second electrode layer and the encapsulation layer;
the light-extracting layer is located at a side of the second electrode layer away from the array substrate, the touch layer is located at a side of the encapsulation layer close to the array substrate, and the polarizing layer is located between the light-extracting layer and the touch layer; and
the light-shielding layer is located at any one or more positions between the second electrode layer and the light-extracting layer, between the light-extracting layer and the polarizing layer, between the polarizing layer and the touch layer, and between the touch layer and the encapsulation layer.

14. The display panel according to claim 2, further comprising a first substrate disposed in the display area and stacked on the array substrate, and the encapsulation layer and the first substrate are both light-transmitting structures.

15. The display panel according to claim 1, wherein the light-shielding area has a width of 0.3-0.5 mm.

16. A display apparatus comprising the display panel according to claim 1.
